(19) United States
(12) Patent Application Publication
(10) Pub. No.: US 2014/0048125 A1
(43) Pub. Date: Feb. 20, 2014

(54) SOLAR CELL BACKSHEET WITH IMPROVED ADHESION TO ENCAPSULANT

(71) Applicants: Bo Fu, Shanghai (CN); Qiuju Wu, Shanghai (CN)

(72) Inventors: Bo Fu, Shanghai (CN); Qiuju Wu, Shanghai (CN)

(73) Assignee: E I DU PONT DE NEMOURS AND COMPANY, Wilmington, DE (US)

(21) Appl. No.: 14/113,583

(22) PCT Filed: May 29, 2012
(86) PCT No.: PCT/CN12/76222

§ 371 Date: Oct. 24, 2013

(30) Foreign Application Priority Data
Jun. 7, 2011 (CN) 201110158380.8

(51) Int. Cl. H01L 31/048; C08J 5/18; B32B 27/08

(52) U.S. Cl. CPC H01L 31/0487; B32B 27/08; C08J 5/18
USPC 136/251; 136/259; 428/421; 264/345; 264/493; 264/485; 264/482

(57) ABSTRACT

Disclosed herein is a heat pressed multi-layer fluoropolymer film or sheet having improved bonding strength to a polyolefin film or sheet and methods for preparing the same, and which methods comprise the steps of (i) providing a multi-layer fluoropolymer film or sheet comprising an oriented fluoropolymer film or sheet layer and an oriented polyester film or sheet layer that is laminated to the oriented fluoropolymer film or sheet layer, wherein the oriented fluoropolymer film or sheet layer is positioned to provide one of the two outer surface layers of the multi-layer fluoropolymer film or sheet, and wherein the oriented fluoropolymer film or sheet layer consists essentially of a fluoropolymer and the oriented polyester film or sheet layer consists essentially of a polyester: and (ii) heat pressing the multi-layer fluoropolymer film or sheet by a heat press means, wherein the heat press means is set at such conditions that the multi-layer fluoropolymer film or sheet receives a pressure of about 0.01-50 Kgf/cm² and a heat of about 150° C.-260° C. Further disclosed herein solar cell modules comprising backsheets formed of the heat pressed multi-layer fluoropolymer films or sheets.

### FIELD OF DISCLOSURE

The disclosure herein is a multi-layer fluoropolymer film or sheet with improved adhesion to other polymeric material and solar cell modules comprising the same.

### BACKGROUND

In solar cell modules, electrically interconnected solar cells are often encapsulated by front and back encapsulant materials and the encapsulated solar cells are then sandwiched by a transparent frontsheet and a backsheet. The backsheets of the solar cell modules are used as supports and barriers from the environment. Among the prior art backsheets, those comprising fluoropolymers (such as those having a multi-layer structure of polyvinyl fluoride/polyethylene terephthalate /polyvinyl fluoride (PVF/PET/PVF)) have been used widely due to their superior weatherability, mechanical, electrical and barrier properties. However, one drawback of such fluoropolymer containing backsheets is that the bonding between the fluoropolymer film and the encapsulant material (e.g., ethylene/vinyl acetate copolymer (EVA)) may deteriorate over time and therefore cause de-lamination of the solar cell modules. Thus, there is still a need to develop fluoropolymer containing backsheets having good adhesion to the encapsulant material.

### SUMMARY

The purpose of the present disclosure is to provide a method for obtaining a heat pressed multi-layer fluoropolymer film or sheet that has improved bonding strength to a polyolefin film, the method comprising, (i) providing a multi-layer fluoropolymer film or sheet comprising a first oriented fluoropolymer film or sheet layer that is laminated to an oriented polyester film or sheet layer, wherein the first oriented fluoropolymer film or sheet layer consists essentially of fluoropolymer and the oriented polyester film or sheet layer consists essentially of polyester, and wherein the first oriented fluoropolymer film or sheer layer provides one of the two opposite outer surface layers of the multi-layer fluoropolymer film or sheet; and (ii) heat pressing the multi-layer fluoropolymer film or sheet by a hear press means, wherein the heat press means is set at such conditions that the mufti-layer fluoropolymer film or sheet receives a pressure of 0.01-50 Kgf/cm² and a heat of 150° C.-260° C.

In one embodiment of the method, the heat press means used in step (ii) is set at such conditions that the multi-layer fluoropolymer film or sheet receives a pressure of 0.1-50 Kgf/cm², or preferably 0.5-50 Kgf/cm², or more preferably 0.5-30 Kgf/cm² and a heat of 150° C.-245° C., or preferably 160° C.-220° C., or more preferably 160° C.-200° C.

In a further embodiment of the method, heat press means used in step (ii) is a pair of hot flat plates and the multi-layer fluoropolymer film or sheet is heat pressed between the hot flat plates for 0.1-30 sec, or preferably 0.5-30 sec, or more preferably 0.5-20 sec.

in a yet further embodiment of the method, the heat press means used in step (ii) comprises one or more pairs of heated nip rolls and the multi-layer fluoropolymer film or sheet is passed through the one or more pairs of heated nip rolls at a line speed of 0.01-100 m/min, or preferably 0.1-50 m/min, or more preferably 0.5-30 m/min,

In a yet further embodiment of the method, wherein, prior to step (ii), the multi-layer fluoropolymer film or sheet is pre-heated to a temperature of 150° C.-260° C., or preferably 150° C.-245° C., or more preferably 160° C.-220° C., or yet more preferably 160° C.-200° C. And the multi-layer fluoro polymer film or sheet may be pre-heated by infra-red heat, air heat, flame heat, electron beam, or laser; or preferably the multi-layer fluoropolymer film or sheet is heated by an infra-red oven.

In a yet further embodiment of the method, the fluoropolymer is derived from fluoromonomers selected from the group consisting of vinyl fluorides, vinylidene fluorides, tetrafluoroethylenes, hexafluoropropylenes, fluorinated ethylene propylenes, perfluoroalkoxys, chlorotrifluoroethlyenes, and combinations of two or more thereof. Or, the fluoropolymer may be selected from the group consisting of polyvinyl fluorides, polyvinylidene fluorides, and combinations thereof; or preferably from polyvinyl fluorides.

In a yet further embodiment of the method, the polyester is selected from he group consisting of polyethylene terephthalates, polybutylene terephthalates, polytrimethylene terephthalates, polyethylene naphthalates, and combinations of two or more thereof; or preferably from polyethylene terephthalates.

In a yet further embodiment of the method, the multi-layer fluoropolymer film or sheet is in the form of a bi-layer film or sheet that consists essentially of the first oriented fluoropolymer film or sheet layer and the oriented polyester film or sheet layer. In such embodiments, the multi-layer fluoropolymer film or sheet may be in the form of a tri-layer film or sheet that consists essentially of the first oriented fluoropolymer film or sheet layer, the oriented polyester film or sheet layer, and a second oriented fluoropolymer film or sheet layer consisting essentially of fluoropolymer that is the same or different from the fluoropolymer forming the first oriented fluoropolymer film or sheet layer, and wherein the oriented polyester film or sheet layer is laminated between the first and the second oriented fluoropolymer film or sheet layers and the first and second oriented fluoropolymer film or sheet layers provide two opposite outer surface layers of the multi-layer fluoropolymer film or sheet.

Further provided herein is a heat pressed multi-layer fluoropolymer film or sheet prepared by any of the methods described above.

In one embodiment of the heat pressed multi-layer fluoropolymer film or sheet, the heat pressed multi-layer fluoropolymer film or sheet is laminated to a polyolefin film or sheet in such a way that the first fluoropolymer film or sheet layer is positioned next to the polyolefin film or sheet, and the bonding strength between the heat pressed multi-layer fluoropolymer film or sheet and the polyolefin film or sheet, measured according to ASTM D903-38, is at least 17 N/cm, or preferably at least 20 N/cm, or more preferably at least 40 N/cm. In such embodiments, the polyolefin film or sheet comprises a polyolefinic composition, wherein the polyolefinic composition comprises a material selected from the group consisting of ethylene/vinyl acetate copolymers, ionomers, polyethylenes, ethylene/acrylate ester copolymers, acid copolymers, and combinations of two or more thereof; or preferably from ethylene/vinyl acetate copolymers.

Yet further provided herein is a solar cell module comprising one or a plurality of solar cells, a back encapsulant sheet laminated to a back side of the solar cells, and a backsheet laminated to a back side of the back encapsulant sheet, wherein the back encapsulant sheet comprises a polyolefin, and wherein the backsheet is formed of any of the heat pressed multi-layer fluoropolymer films or sheets described above.

In one embodiment of the solar cell module, the polyolefin comprising the back encapsulant sheet is selected from the group consisting of ethylene/vinyl acetate copolymers, ionomers, polyethylenes, ethylene/acrylate ester copolymers, acid copolymers, and combinations of two or more thereof; or preferably from ethylene/vinyl acetate copolymers.

In accordance with the present disclosure, when a range is given with two particular end points, it is understood that the range includes any value that is within the two particular end points and any value that is equal to or about equal to any of the two end points.

### DETAILED DESCRIPTION

Disclosed herein is a heat pressed multi-layer film or sheet comprising at least one oriented fluoropolymer film or sheet layer (hereinafter “heat pressed multi-layer fluoropolymer film or sheet”). The terms “film” and “sheet” are used interchangeably herein to refer to a continuous thin flat structure with a uniform thickness. In general, a sheet may have a thickness greater than about 100 μm while a film may have a thickness of about 100 μm or less. In accordance with the present disclosure, the heat pressed multi-layer fluoropolymer film or sheet is obtained by: (a) providing a multi-layer fluoropolymer film or sheet comprising an oriented fluoropolymer film or sheet layer and an oriented polyester film or sheet layer that is laminated to the oriented fluoropolymer film or sheet layer, wherein the oriented fluoropolymer film or sheet layer is positioned to provide one of two opposite outer surface layers of the multi-layer fluoropolymer film or sheet, and wherein the oriented fluoropolymer film or sheet layer comprises or consists essentially of a fluoropolymer and the oriented polyester film or sheet layer comprises or consists essentially of a polyester; and (b) heat pressing the multi-layer fluoropolymer film or sheet by a heat press means, wherein the heat press means is set at such conditions that the multi-layer fluoropolymer film or sheet receives a pressure of about 0,01-50 kilograms-force per square centimeter (Kgf/cm²) and a heat of about 150° C.-260° C.

When it is said that a film or sheet “comprises or consists essentially of (a particular polymer) it is meant that the film or sheet is made from (i) a material comprising the particular polymer and other components or (ii) a material consisting of the particular polymer and optionally certain other components, provided that the inclusion of the certain other components do not negatively affect the mechanical, physical, and adhesion properties of the film or sheet.

The term “oriented”, as used herein, refers to an orientation process, under which a polymeric film or sheet is un-axially or bi-axially stretched in transverse and/or machine directions to achieve a combination of mechanical and physical properties. Stretching apparatus and processes to obtain uni-axially or bi-axially oriented films or sheets are known in the art and may be adapted by those skilled in the art to produce the films or sheets disclosed herein. Examples of such apparatus and processes include, for example, those disclosed in U.S. Pat. Nos, 3,278,663; 3,337,665; 3,456,044; 4,590,106; 4,760,116; 4,769,421; 4,797,235; and 4,886,634.

The oriented fluoropolymer films or sheets used herein may comprise or consist essentially of a fluoropolymer derived from fluoromonomers selected from vinyl fluorides (VF), vinylidene fluorides (VDF), tetrafluoroethylenes (TFE), hexafluoropropylenes (HFP), fluorinated ethylene propylenes (FEP and EFEP), perfluoroalkoxys (PFA), chlorotrifluoroethlyenes (CTFE), and combinations of two or more thereof. More specific exemplary fluoropolymers used herein include, without limitation, polyvinyl fluorides (PVF), polyvinylidene fluorides (PVDF), ethylene chlorotrifluoroethlyene copolymers (ECTFE), polychlorotrifluoroethylene (PCTFE), ethylene tetrafluoroethylene copolymers (ETFE), and combinations of two or more thereof (such as THV, a combination of TFE, HFP and VDF). In some embodiments, fluoropolymers or fluoromonomers may be copolymerized or blended with non-fluoropolymers to form oriented fluoropolymer films or sheets (such as HTE, a combination of HFP, TFE and ethylene).

In one embodiment, oriented fluoropolymer films or sheets used herein are oriented PVF films or sheets comprising or consisting essentially of PVF, which is a thermoplastic fluoropolymer with repeating units of —(CH₂CHF)ₙ—. PVF may be prepared by any suitable process, such as those disclosed in U.S. Pat. No. 2,419,010. In general, PVF has insufficient thermal stability for injection molding and is thus usually made into films or sheets via a solvent extrusion or casting process. In accordance with the present disclosure, the oriented PVF film or sheet may be prepared by any suitable process, such as casting or solvent assisted extrusion. For example, U.S. Pat. No. 2,953,818 discloses an extrusion process for the preparation of orientable films from PVF and U.S. Pat. No. 3,139,470 discloses a process for preparing oriented PVF films.

Also in accordance with the present disclosure, the oriented fluoropolymer films or sheets used herein may also include those that have undergone various surface treatments to improve their bonding properties to other films or sheets. Exemplary surface treatments include, without limitation, chemical treatment (see e.g., U.S. Pat. No. 3,122,445), flame treatment (see e.g., U.S. Pat. No. 3,145,242), and electrical discharge treatment (see e.g., U.S. Pat. No. 3,274,088).

The oriented PVF films or sheets used herein may also be obtained commercially. For example, suitable oriented PVF films or sheets may be purchased from E.I. du Pont de Nemours and Company (U.S.A.) (hereafter “DuPont”) under the trade name Tedlar®.

In another embodiment, the oriented fluoropolymer films or sheets used herein are oriented PVDF films or sheets comprising or consisting essentially of PVDF, which is a thermoplastic fluoropolymer with repeating units of —(CH₂CF₂)ₙ—. Commercially available oriented PVDF films or sheets, include, without limitation, Kynar™ PVDF films from Arkema Inc. (U.S.A.) and Denka DX films from Denka Group (Japan).

The oriented polyester films or sheets used herein may comprise or consist essentially of a polyester selected from polyethylene terephthalates (PET), polybutylene terephthalates (PBT), polytrimethylene terephthalates (PTT), polyethylene naphthalates (PEN), and combinations of two or more thereof. In a preferred embodiment, the oriented polyester film or sheet comprises or consists essentially of PET, Useful polyesters may be branched or linear, vary in density and molecular weight, and combinations thereof.

In addition to the oriented fluoropolymer film or sheet layer and the oriented polyester film or sheet layer, the multi-layer fluoropolymer film or sheet may optionally further comprise other additional layers. For example, in one embodiment, the multi-layer fluoropolymer film or sheet used herein is in the form of a bi-layer film or sheet that consists essentially of a first outer surface layer formed of an oriented fluoropolymer film or sheet (e.g. an oriented PVF film or sheet) and a second (opposite) outer surface layer formed of an oriented polyester film or sheet (e.g., an oriented PET film or sheet). Such bi-layer fluoropolymer film or sheet may be denoted herein, e.g., as a “PVF/PET” bi-layer film or sheet. In a further embodiment, the multi-layer fluoropolymer film or sheet is in the form of a tri-layer film or sheet that consists essentially of two opposite outer surface layers each formed of an oriented fluoropolymer film or sheet (e.g., oriented PVF films or sheets) and an inner layer formed of an oriented polyester film or sheet (e.g., an oriented PET film or sheet). Such tri-layer fluoropolymer film or sheet may be denoted herein, e.g., as a “PVF/PET/PVF” tri-layer film or sheet. As used herein, when a multi-layer film or sheet is said to “consist essentially of”, it is meant that, in addition to the listed component layers, adhesives may or may not be also included in the subject multi-layer film or sheet to improve the bonding between the component layers. Thus, in accordance with the present disclosure, adhesives may be used between any pair of adjacent layers of the mufti-layer fluoropolymer films or sheets to improve the bonding strength therebetween. Suitable adhesives may include, but are not limited to, polyurethanes, acrylics, epoxies, polyolefins and combinations of two or more thereof. The multi-layer fluoropolymer films or sheets may be prepared by any suitable process, such as dry lamination or extrusion lamination.

The multi-layer fluoropolymer films or sheets used herein may be obtained commercially. For example, suitable multi-layer fluoropolymer films or sheets may be purchased from Isovolta AG (Austria) under the trade name Icosolar™; Krempel GMBH (Germany) under the trade name AKASOL™: or Taiflex Scientific Co. Ltd. (Taiwan) under the trade name Solmate™.

The heat pressing process disclosed herein includes setting the heat press means at such conditions that the multi-layer fluoropolymer film or sheet receives a pressure of about 0.01-50 Kgf/cm², or about 0.1-50 Kgf/cm², or about 0.5-50 Kgf/cm², or about 0.5-30 Kgf/cm², and a heat of about 150° C.-260° C., or about 150° C.-245° C., or about 160° C.-220° C., or about 160° C.-200° C. As use d herein, “receives a pressure of” means that the film or sheet is subjected to an average pressure of a certain force per unit area over the heat pressed portion of the film or sheet. As used herein, “receives a heat of” means that as the film or sheet is contacted with a pressing surface that is heated to a certain temperature, the pressing surface applies the heat to the heat pressed portion of the film or sheet.

Any suitable heat press means may be used herein, which may include, without limitation, nip rolls, calendar rolls, flat bed laminators and hot flat plate press machines. In one embodiment, two or more rolls may be used in a horizontal or vertical configuration to heat press a multi-layer fluoropolymer film. In a more specific embodiment, a three-roll extrusion coating line (model number KXE1222, Davis-Standard, U.S.A.) with a horizontal roll configuration may be used. A multi-layer fluoropolymer film or sheet may be unwound and passed between an upstream roll (steel) and a central roll (rubber) under heat and pressure, and then cooled by a downstream roll (PTFE sleeved) before being wound up. The roll temperatures, the line speed, and the nip pressure (i.e., the pressure imposed on the films by the upstream and central rolls) can all be adjusted. A film or sheet may receive a heat that is the surface temperature of the heated rolls (e.g., the upstream steel roll and central rubber roll). The surface temperatures of the heated rolls may be the same or different. In one embodiment, the upstream steel roll may be at a higher temperature than the central rubber roll. When the film or sheet is pressed between two rolls having different surface temperatures, the film or sheet receives a heat that is the combined average temperature of the two rolls. In another embodiment, multiple nip rolls may be used to further control the heat pressing of the multi-layer fluoropolymer film.

In those embodiments wherein a pair of hot flat plates is used, it is preferred that the multi-layer fluoropolymer films or sheets are kept under pressure for about 0.1-30 sec, or about 0.5-30 sec, or about 0.5-20 sec. In those embodiments wherein heated nip rolls or calendar rolls are used, it is preferred that the line speed of the rolls are kept at about 0.01-100 m/min, or about 0.1-50 m/min, or about 0.5-30 m/min. Further, in certain embodiments, the heat pressing process may further comprise a pre-heating step wherein the multi-layer fluoropolymer film or sheet is pre-heated to a temperature of about 150° C.-260° C. by a heating source prior to the heat pressing step. The heating source used herein may include, without infra-red (IR) heat (e.g., an IR oven), air heat, flame heat, electron beam and laser, and the like. In one embodiment, the multi-layer fluoropolymer film or sheet is first pre-heated (e.g., by an IR oven) to a temperature of about 150° C.-260° C. and then placed and pressed between a pair of hot flat plates for about 0.1-30 sec, wherein the pair of hot flat plates is set at such conditions that the film or sheet receives a pressure of about 0.05-50 Kgf/cm² and a heat of about 150° C.-260° C.

In one embodiment, the multi-layer fluoropolymer film or sheet is first pre-heated (e.g., by an IR oven) to a temperature of about 150° C.-260° C. and then passed between at least one pair of heated nip rolls, wherein the at least one pair of heated nip rolls is set at a line speed of about 0.01-100 m/min and other conditions are set such that the film or sheet receives a pressure of about 0.05-50 Kgf/cm² and a heat of about 150° C.-260° C. Those skilled in the art will understand that a variety of configurations may be used for controlling the heating, pressing and cooling of the multi-layer fluoropolymer film.

In one embodiment, the heat pressed multi-layer fluoropolymer film or sheet disclosed herein may have a total thickness of about 10-500 μm, or about 50-400 μm, or about 75-350 μm, while each of the oriented fluoropolymer film or sheet layers may have a thickness of about 5-100 μm, or about 10-50 μm, or about 20-40 μm, while each of the oriented polyester film or sheet layers may have a thickness of about 5-500 μm, or about 50-350 μm, or about 100-300 μm.

As demonstrated by the examples provided herebelow, when the heat pressed multi-layer fluoropolymer film or sheet disclosed herein was laminated to an ethylene/vinyl acetate copolymer (EVA) sheet in such a way that the outer surface layer of the oriented fluoropolymer film or sheet was in direct contact with the EVA sheet, the bonding strength between the multi-layer fluoropolymer film or sheet and the EVA sheet was very much improved compared to the bonding strength between a multi-layer fluoropolymer film or sheet that was not heat pressed and an EVA sheet. For example, when a prior art multi-layer fluoropolymer film or sheet was laminated to an EVA sheet, its bonding strength to the EVA sheet was only 10.1 N/cm. However, when a heat pressed multi-layer fluoropolymer film or sheet (as described above) was laminated to an EVA sheet in the same manner, its bonding strength to the EVA sheet could be increased to up to 107.9 N/cm.

Therefore, in accordance with the present disclosure, when the heat pressed multi-layer fluoropolymer film or sheet is laminated to a polyolefin film or sheet (e.g., an EVA film or sheet), the bonding strength between the heat pressed multi-layer fluoropolymer film or sheet and the polyolefin film or sheet may reach a level of at least about 17 N/cm, or at least about 20 N/cm, or at least about 40 N/cm.

Further disclosed herein is a solar cell module comprising one or a plurality of solar cells, a back encapsulant sheet laminated to a backside of the solar cells, and a backsheet laminated to a backside of the back encapsulant sheet, wherein the back encapsulant sheet comprises a polyolefin, and wherein the backsheet is formed of the heat pressed multi-layer fluoropolymer film or sheet disclosed above.

The solar cells used herein may be any photoelectric conversion device that can convert solar radiation to electrical energy. In one embodiment, solar cells may be formed of photoelectric conversion bodies with electrodes formed on both main surfaces thereof. The photoelectric conversion bodies may be made of any suitable photoelectric conversion materials, such as, crystalline silicon (c-Si), amorphous silicon (a-Si), microcrystalline silicon (pc-Si), cadmium telluride (CdTe.), copper indium selenide (CuInSe₂ or CIS), copper indium/gallium diselenide (CuInₓGa₍₁₋ₓ₎Se₂ or CIGS), light absorbing dyes, and organic semiconductors. The front electrodes may be formed of conductive paste, such as silver paste, applied over the front surface of the photoelectric conversion body by any suitable printing process, such as screen printing or ink-jet printing. The front conductive paste may comprise a plurality of parallel conductive fingers and one or more conductive bus bars perpendicular to and connecting the conductive fingers, while the back electrodes may be formed by printing metal paste over the entire back surface of the photoelectric conversion body. Suitable metals forming the back electrodes include, but are not limited to, aluminum, copper, silver, gold, nickel, molybdenum, cadmium, and alloys thereof. In another embodiment, both electrodes of the photoelectric conversion body can be on the same surface thereof. In a particular embodiment, both the anode and cathode are located on the back surface of the photoelectric conversion body, forming a back contact solar cell.

When in use, the solar cells typically have a front (or top) surface facing towards the solar radiation and a back (or bottom) surface facing away from the solar radiation. Therefore, each component layer within a solar cell module has a front surface (or side) and a back surface (or side).

In accordance with the present disclosure, the back encapsulant sheet that is laminated to the back side of the solar cells may comprise a polyolefin, including without limitation, ethylene/vinyl acetate copolymers (EVA), ionomers, polyethylenes, ethylene/acrylate ester copolymers (such as polyethylene-co-methyl acrylate) and poly(ethylene-co-butyl acrylate)), acid copolymers, and combinations of two or more thereof. In one embodiment, the back encapsulant sheet comprises EVA. EVA-based encapsulant sheets useful herein can be commercially obtained from Bridgestone (Japan) under the trade name EVASKY™; Sanvic Inc. (Japan) under the trade name Ultrapearl™; Bixby International Corp. (U.S.A.) under the trade name BixCure™; or RuiYang Photovoltaic Material Co. Ltd, (China) under the trade name Revax™. Exemplary ionomer-based encapsulant sheets include, without limitation, DuPont™ PV5300 series encapsulant sheets and DuPont™ PV5400 series encapsulant sheets from DuPont.

In one embodiment, the backsheet of the solar cell module is formed of the heat pressed tri-layer fluoropolymer film or sheet disclosed above (for example with a structure of fluoropolymer/polyester/fluoropolymer, or more particularly PVF/PET/PVF). In a further embodiment, the backsheet is formed of the heat pressed bi-layer fluoropolymer film or sheet disclosed above (for example with a structure of fluoropolymer/polyester, or more particularly PVF/PET).

The solar cell modules disclosed herein may further comprise a transparent front encapsulant sheet laminated to a front surface of the solar cell(s), and a transparent frontsheet further laminated to a front surface of the front encapsulant sheet.

Suitable materials for the transparent front encapsulant sheet include without limitation, compositions comprising EVA, ionomers, polyvinyl butyral) (PVB), polyurethane (PU), polyvinylchloride (PVC), polyethylenes, polyolefin block elastomers, ethylene/acrylate ester copolymers (such as polyethylene-co-methyl acrylate) and polyethylene-co-butyl acrylate)), acid copolymers, silicone elastomers, epoxy resins, and the like.

Any suitable glass or plastic sheets can be used as the transparent front sheet. Suitable materials for the plastic frontsheet may include, without limitation, glass, polycarbonate, acrylics, polyacrylate, cyclic polyolefins, ethylene norbornene polymers, metallocene-catalyzed polystyrene, polyamides, polyesters, fluoropolymers and the like and combinations thereof.

Any suitable lamination process may be used to produce the solar cell modules disclosed herein. In one embodiment, the process includes: (a) providing a plurality of electrically interconnected solar cells; (b) forming a pre-lamination assembly wherein the solar cells are laid over a back encapsulant sheet, which is further laid over a backsheet, wherein the backsheet is formed of the heat pressed multi-layer fluoropolymer film or sheet disclosed above; and (c) laminating the pre-lamination assembly under heat and pressure.

In a further embodiment, the process includes: (a) providing a plurality of electrically interconnected solar cells; (b) forming a pre-lamination assembly wherein the solar cells are sandwiched between a transparent front encapsulant sheet and a back encapsulant sheet, which is further sandwiched between a transparent frontsheet and a backsheet, wherein the backsheet is formed of the heat pressed multi-layer fluoropolymer film or sheet disclosed above; and (c) laminating the pre-lamination assembly under heat and pressure.

In one embodiment, the module lamination process is performed using a ICOLAM 10108 laminator purchased from Meier Solar Solutions GmbH (Germany) at about 135-150C and about 1 atm for about 10-25 minutes.

### EXAMPLES

### Materials Used:

PVF film: Tedlar® PV2001, an oriented polyvinyl fluoride film (38 μm thick) obtained from DuPont;
EVA sheet: Revax™767 ( [symbol] 767) ethylene/vinyl acetate copolymer sheet (500 μm thick) obtained from RuiYang Photovoltaic Material Co. Ltd. (China);
PET film: corona treated (both sides) Melinex™ S oriented polyethylene terephthalate film (250 μm thick) obtained from DuPont Teijin Films (U.S.A.);
PVF/PET/PVF film: a laminated tri-layer film having a structure of “PVF film/PET film/PVF film”, which was prepared by laminating one layer of PET film between two layers of PVF films using Liofol LA 2692 polyurethane adhesives and hardener UR7395 (both purchased from Henkel AG&Co., Germany) at a ratio of 11:1.

### Comparative Examples CE1-CE3 and Examples E1-E9

In CE1, a number of laminated sheets having a structure of “glass/EVA sheet/PVF/PET/PVF film” were prepared by first positioning one layer of an EVA sheet (7×10 cm) between one layer of a 3.2 mm thick glass sheet (7×10 cm) and one layer of PVF/PET/PVF film (7×12 cm), that was not heat pressed, to form a multi-layer pre-lamination assembly, which was then subject to vacuum lamination at 145° C. and 1 atm for 15 minutes (using a ICOLAM 10/08 laminator) to form the final laminated sheets. In additional, about half way along the length of the pre-lamination structure, a piece of fluorinated ethylene propylene (FEP) release film was positioned between the EVA sheet and the PVF/PET/PVF film prior to vacuum lamination process. This way, after removing the FEP release film, the PVF/PET/PVF film would have a loose end that is not bonded to the EVA sheet. Thereafter, along the length of each of the laminated sheets, two test strips (2.54 cm wide and 12 cm long) were cut out and the bonding strength between the PVF/PET/PVF film and the EVA sheet were measured in accordance with ASTM D903-98 using an Instron 5566 tester (purchased from Instron (U.S.A.)). The bonding strength of a total of 6 strips prepared as so was measured and their average was calculated and tabulated in Table 1.

In CE2-CE3 and E1-E9, a number of heat pressed PVF/PET/PVF films were obtained by placing PVF/PET/PVF films in an infrared (IR) oven (Model Number 10831010, purchased from Shanghai Yuejin Medical Instruments Factory, China) for a certain period of time, followed by pressing the heated PVF/PET/PVF films between a pair of hot flat plates for a certain period of time. The temperature of the IR oven, the residence time of the films in the IR oven, the temperature of the hot flat plates, the pressure that was imposed on the films by the hot flat plates, and the residence time of the films being pressed by the hot flat plates are listed in Table 1.

By the same lamination process described above in CE1, laminated sheets of “glass/EVA sheet/heat pressed PVF/PET/PVF film” were prepared and the bonding strength between the heat pressed PVF/PET/PVF films and the EVA sheets in each of the examples (CE2-CE3 and E1-E9) were determined by the same method used in CE1 and tabulated in Table 1.

TABLE 1

| | Temperature | Time in | Temperature of | Time between | Pressure of | ³Bonding |
|---|---|---|---|---|---|---|
| | of IR Oven | IR Oven | Hot Plates | Hot Plates | Hot Plates | Strength |
| Sample | (° C.) | (seconds) | (° C.) | (seconds) | (Kgf/cm²) | (N/cm) |
| CE1 | ²NA | ²NA | ²NA | ²NA | ²NA | 10.1 |
| E1 | 210 | 10 | 210 | 1 | 10.55 | 81.1 |
| ¹E2 | ²NA | ²NA | 210 | 1 | 10.55 | 65.3 |
| E3 | 210 | 10 | 190 | 2 | 10.55 | 18.5 |
| E4 | 220 | 10 | 220 | 1 | 10.55 | 84.1 |
| ¹E5 | ²NA | ²NA | 220 | 1 | 10.55 | 60.5 |
| E6 | 210 | 10 | 190 | 3 | 10.55 | 19.8 |
| CE2 | 150 | 10 | 150 | 3 | 10.55 | 10.3 |
| E7 | 160 | 10 | 160 | 10 | 10.55 | 17.8 |
| CE3 | 150 | 10 | 150 | 10 | 10.55 | 10.3 |
| E8 | 210 | 10 | 190 | 10 | 10.55 | 25.3 |
| ¹E9 | ²NA | ²NA | 190 | 10 | 10.55 | 19.6 |

Note:
¹In examples E2, E5, and E9, the PVF/PET/PVF film underwent hot plate pressing without the heat treatment by IR ovens;
²NA stands for “not applicable”;
³The bonding strength measured was between the PVF/PET/PVF film (heat pressed PVF/PET/PVF films in CE2-CE3 and E1-E9) and the EVA sheet.

As demonstrated above, the heat pressed PVF/PET/PVF films disclosed herein had improved bonding strength with the EVA sheets (ranging from 17.8-84.1 N/cm in E1-E9) compared to that of the PVF/PET/PVF films that were not heat pressed (10.1 N/cm in CE1).

### Comparative Examples CE4 and Examples E10-E22

In CE4 and E10-22, a number of heat pressed PVF/PET/PVF films were obtained using a three-roll extrusion coating line (model number KXE1222, purchased from Davis-Standard, U.S.A.). Specifically, the PVF/PET/PVF films were first pressed and then passed between the upstream rolls (heated steel rolls) and the central rolls (heated rubber rolls), and then cooled by the downstream rolls (PTFE sleeved rolls) before being wound up. The roll temperatures, the line speed, and the nip pressure (i.e., the pressure imposed on the films by the upstream and central rolls) are listed in Table 2. For Examples E19-E22, the downstream roll was not heated (i.e., the roll was operated at room temperature). Roll temperatures for the upstream, central and downstream rolls are the average surface temperatures of each roll measured along the length of the roll (i.e., at multiple locations) for a given set temperature of the oil bath used to heat the roll.

By the same process described above in CE1, laminated sheets of “glass/EVA sheet /heat pressed PVF/PET/PVF film” were prepared and the bonding strength between the heat pressed PVF/PET/PVF films and the EVA sheets in each of the examples (CE4 and E10-22) were determined by the same method used in CEI and tabulated in Table 2.

TABLE 2

| | | | Combined Avg | | | | |
|---|---|---|---|---|---|---|---|
| | Upstream | Central | Temp Upstream | Downstream | Line | Nip | ²Bonding |
| | Roll Temp | Roll Temp | & Central | Roll Temp | Speed | Pressure | Strength |
| Sample | (° C.) | (° C.) | Rolls (° C.) | (° C.) | (m/min) | (Kgf/cm²) | (N/cm) |
| CE1 | ¹NA | ¹NA | ¹NA | ¹NA | ¹NA | ¹NA | 10.1 |
| E10 | 205 | 163 | 184 | 75 | 10 | 3 | 70.0 |
| E11 | 212 | 181 | 196.5 | 75 | 20 | 3 | 54.7 |
| CE4 | 144 | 120 | 132 | 135 | 10 | 3 | 10.3 |
| E12 | 172 | 148 | 160 | 75 | 10 | 3 | 24.9 |
| E13 | 164 | 140 | 152 | 75 | 1 | 5 | 18.9 |
| E14 | 205 | 163 | 184 | 75 | 10 | 3 | 76.6 |
| E15 | 212 | 181 | 196.5 | 75 | 10 | 3 | 64.6 |
| E16 | 219 | 186 | 202.5 | 75 | 10 | 5 | 31.9 |
| E17 | 212 | 181 | 196.5 | 75 | 20 | 5 | 60.2 |
| E18 | 205 | 176 | 190.5 | 75 | 20 | 5 | 62.4 |
| E19 | 205 | 132 | 168.5 | ¹NA | 3 | 5 | 107.9 |
| E20 | 205 | 132 | 168.5 | ¹NA | 5 | 5 | 98.3 |
| E21 | 205 | 132 | 168.5 | ¹NA | 10 | 5 | 92.1 |
| E22 | 205 | 132 | 168.5 | ¹NA | 20 | 5 | 4.8 |

¹NA stands for “not applicable”;
²The bonding strength measured was between the PVF/PET/PVF film (heat pressed PVF/PET/PVF films in CE4 and E10-E22) and the EVA sheet.

As demonstrated herein, the heat pressed PVF/PET/PVF films disclosed herein, had improved bonding strength with the EVA sheets (ranging from 18.9-107.9 N/cm in E10-E21) compared to that of the PVF/PET/PVF films that were not heat-pressed (10.1 N/cm in CE1). In Example E22, the bonding strength between the film and the EVA sheet was high, but the film itself separated at the PVF/PET interface.

1. A method for obtaining a heat pressed multi-layer fluoropolymer film or sheet that has improved bonding strength to a polyolefin film, the method comprising, (i) providing a multi-layer fluoropolymer film or sheet comprising a first oriented fluoropolymer film or sheet layer that is laminated to an oriented polyester film or sheet layer, wherein the first oriented fluoropolymer film or sheet layer consists essentially of fluoropolymer and the oriented polyester film or sheet layer consists essentially of polyester, and wherein the first oriented fluoropolymer film or sheet layer provides one of the two opposite outer surface layers of the multi-layer fluoropolymer film or sheet; and (ii) heat pressing the multi-layer fluoropolymer film or sheet by a heat press means, wherein the heat press means is set at such conditions that the multi-layer fluoropolymer film or sheet receives a pressure of 0.01-50 Kgf/cm² and a heat of 150° C-260° C.

2. The method of claim 1, wherein in step (ii), the heat press means is set at such conditions that the multi-layer fluoropolymer film or sheet receives a pressure of 0.1-50 Kgf/cm², or preferably 0.5-50 Kgf/cm², or more preferably 0.5-30 Kgf/cm² and a heat of 150° C.-245° C., or preferably 160° C.-220° C., or more preferably 160° C.-200° C.

3. The method of claim 1, wherein the heat press means is a pair of hot flat plates and in step (ii), the multi-layer fluoropolymer film or sheet is heat pressed between the hot flat plates for 0.1-30 sec, or preferably 0.5-30 sec, or more preferably 0.5-20 sec.

4. The method of claim 1, wherein the heat press means comprises one or more pairs of heated nip rolls and in step (ii), the multi-layer fluoropolymer film or sheet is passed through the one or more pairs of heated nip rolls at a line speed of 0.01-100 m/min, or preferably 0.1-50 m/min, or more preferably 0.5-30 m/min.

5. The method of claim 1, wherein, prior to step (ii), the multi-layer fluoropolymer film or sheet is pre-heated to a temperature of 150° C.-260° C., or preferably 150° C.-245° C., or more preferably 160° C.-220° C., or yet more preferably 160° C.-200° C.

6. The method of claim 5, wherein, prior to step (ii), the multi-layer fluoropolymer film or sheet is pre-heated by infra-red heat, air heat, flame heat, electron beam, or laser; or preferably the multi-layer fluoropolymer film or sheet is heated by an infra-red oven.

7. The method of any of claims 1-6, wherein the fluoropolymer is derived from fluoromonomers selected from the group consisting of vinyl fluorides, vinylidene fluorides, tetrafluoroethylenes, hexafluoropropylenes, fluorinated ethylene propylenes, perfluoroalkoxys, chlorotrifluoroethlyenes, and combinations of two or more thereof.

8. The method of claim 7, wherein the fluoropolymer is selected from the group consisting of polyvinyl fluorides, polyvinylidene fluorides, and combinations thereof; or preferably the fluoropolymer is selected from polyvinyl fluorides.

9. The method of claim 1, wherein the polyester is selected from the group consisting of polyethylene terephthalates, polybutylene terephthalates, polytrimethylene terephthalates, polyethylene naphthalates, and combinations of two or more thereof; or preferably the polyester is selected from polyethylene terephthalates.

10. The method of claim 1, wherein the multi-layer fluoropolymer film or sheet is in the form of a bi-layer film or sheet that consists essentially of the first oriented fluoropolymer film or sheet layer and the oriented polyester film or sheet layer.

11. The method of claim 1, wherein the multi-layer fluoropolymer film or sheet is in the form of a tri-layer film or sheet that consists essentially of the first oriented fluoropolymer film or sheet layer, the oriented polyester film or sheet layer, and a second oriented fluoropolymer film or sheet layer consisting essentially of fluoropolymer that is the same or different from the fluoropolymer of the first oriented fluoropolymer film, wherein the oriented polyester film or sheet layer is laminated between the first and the second oriented fluoropolymer film or sheet layers and the first and second oriented fluoropolymer film or sheet layers provide two opposite outer surface layers of the multi-layer fluoropolymer film or sheet.

12. A heat pressed multi-layer fluoropolymer film or sheet prepared by the method of claim 1.

13. The heat pressed multi-layer fluoropolymer film or sheet of claim 12, wherein the heat pressed multi-layer fluoropolymer film or sheet is laminated to a polyolefin film or sheet in such a way that the first fluoropolymer film or sheet layer is positioned next to the polyolefin film or sheet, and the bonding strength between the heat pressed multi-layer fluoropolymer film or sheet and the polyolefin film or sheet, measured according to ASTM D903-38, is at least 17 N/cm, or preferably at least 20 N/cm, or more preferably at least 40 N/cm.

14. The heat pressed multi-layer fluoropolymer film or sheet of claim 13, wherein the polyolefin film or sheet comprises a polyolefinic composition, and wherein the polyolefinic composition comprises a material selected from the group consisting of ethylene/vinyl acetate copolymers, ionomers, polyethylenes, ethylene/acrylate ester copolymers, acid copolymers, and combinations of two or more thereof; or preferably the polyolefinic composition comprises a material selected from the group consisting of ethylene/vinyl acetate copolymers.

15. A solar cell module comprising one or a plurality of solar cells, a back encapsulant sheet laminated to a back side of the solar cells, and a backsheet laminated to a back side of the back encapsulant sheet, wherein the back encapsulant sheet comprises a polyolefin, and wherein the backsheet is formed of the heat pressed multi-layer fluoropolymer film or sheet recited in claim 12.

16. The solar cell module of claim 15, wherein the polyolefin comprising the back encapsulant sheet is selected from the group consisting of ethylene/vinyl acetate copolymers, ionomers, polyethylenes, ethylene/acrylate ester copolymers, acid copolymers, and combinations of two or more thereof; or preferably the polyolefin comprised in the back encapsulant sheet is selected from ethylene/vinyl acetate copolymers.
